(19) United States
(12) Patent Application Publication
(10) Pub. No.: US 2004/0192060 A1
(43) Pub. Date: Sep. 30, 2004

(54) Method for fabricating a semiconductor structure

(76) Inventors: Maik Stegemann, Dresden (DE); Stephan Wege, Weissig (DE)

Correspondence Address: LERNER AND GREENBERG, PA, P O BOX 2480, HOLLYWOOD, FL, 33022-2480, US

(21) Appl. No.: 10/806,512

(22) Filed: Mar. 22, 2004

(30) Foreign Application Priority Data
Mar. 20, 2003 (DE) 103 12 469.1

(51) Int. Cl. H01L 21/76

(52) U.S. Cl. 438/713; 438/723

(57) ABSTRACT

A method for fabricating a semiconductor structure includes providing a semiconductor substrate and a sacrificial layer between a layer to be patterned and a resist layer, patterning the resist layer to form a patterned resist layer; selectively etching the sacrificial layer with a taper angle so as to reduce the dimensions within the sacrificial layer in the etching direction which are prescribed by depressions situated in the patterned resist layer, and selectively etching the layer to be patterned using the sacrificial layer etched with a taper angle as a mask. The present invention also relates to a method for fabricating a semiconductor structure in which two sacrificial layers are used.

### BACKGROUND OF THE INVENTION

### FIELD OF THE INVENTION

The present invention relates to a method for patterning semiconductor substrates, in which depressions with a reduced critical width are produced.

In modern semiconductor technology, the structures on the surface of the semiconductor substrates that carry the integrated circuits are becoming smaller and smaller. This means that there is also a continual rise in the requirements made of the patterning technology. To meet these requirements, it would be desirable to be able to produce holes or trenches or depressions with smaller lateral dimensions during the patterning of layers of the semiconductor substrate. In particular, it would be desirable for the depressions serving as contact holes to be miniaturized with regard to their lateral extent. This problem arises, e.g., also when producing contact holes during the fabrication of self-aligning contacts. In the transition to smaller technologies, it is necessary to strive to miniaturize the depressions in layers to be patterned.

In principle, the critical width (critical dimension or CD) or the dimensions of depressions is or are determined by the overall patterning, which includes the lithographic method and the etching. To produce smaller structures, attempts have been made hitherto to develop in each case new lithography masks that can be fabricated with smaller openings, if appropriate combined with new lithography exposure installations that enable smaller opening widths.

The etching component in conventional methods has been limited to transferring the critical width of depressions after the lithography into the layer to be patterned by etching processes with a small or zero nm alteration. In the transition to the new technologies with smaller structures, this procedure necessitates an extremely high investment in the lithography area. Other ideas in this respect, which are likewise to be established in the lithography area, are Chemical Amplification of Resist Lines (CARL) and what is referred to as “reflow”. In the case of CARL, a special resist is treated chemically (siliconized), the latter “grows” in the process, is enriched with Si, and the CDs become smaller. This then silicon-rich layer is used for straight patterning by dry etching of a so-called bottom resist. This means that there is available for the actual patterning a resist mask having a greater thickness with smaller dimensions (CD) than at the beginning. The siliconization of the special resist is disadvantageous in this case because it is complicated.

In the case of the lithographic reflow method, existing lithography structures are made to flow by temperature and time, which results in reduced dimensions (CDs) but also a reduced resist thickness. The result is made available to the dry etching as a “new resist mask”.

### SUMMARY OF THE INVENTION

It is accordingly an object of the invention to provide a method for fabricating a semiconductor structure that overcomes the hereinafore-mentioned disadvantages of the heretofore-known devices and methods of this general type and that makes it possible to produce, in semiconductor substrates having layers to be patterned, depressions or holes with a reduced critical width or lateral dimensions, in particular, without having to make changes to the existing lithography equipment.

The present invention is based on the idea of introducing one or a plurality of sacrificial layers, at least one of which is etched with a controlled taper angle. As a result, a reduced opening width or lateral dimension is available for a subsequent patterning of an underlying layer to be patterned. In such a case, the etching of the sacrificial layer, of the sacrificial layers, and/or of the layer to be patterned is in each case effected selectively with respect to the adjacent layers, in particular, the overlying layers used in each case as a mask, i.e., largely without the layer used in each case as a mask being damaged or removed during etching. The invention, thus, solves the problem presented in the introduction in that the reduction of the critical width needed in the context of technological miniaturization is produced by the invention's etching process with taper angle, and not by additional expenditure on lithography. In the methods according to the invention, it is possible to achieve a very good accuracy and controllability of the dimensions with a reduced width. It is, thus, advantageously possible to save capital expenditure in the lithography area or shift it to later generations. In addition, it is possible at the same time to eliminate known problems such as, e.g., insufficient resist selectivity.

With the foregoing and other objects in view, there is provided, in accordance with the invention, a method in which one sacrificial layer is introduced, and relates to a method for fabricating a semiconductor structure, having the following steps:

a. provision of a semiconductor substrate;

b. provision of a sacrificial layer between a layer to be patterned and a resist layer;

c. patterning of the resist layer in order to form a patterned resist layer;

d. selective etching of the sacrificial layer with a taper angle in such a way as to reduce the dimensions within the sacrificial layer in the etching direction that are prescribed by depressions situated in the patterned resist layer; and

e. selective etching of the layer to be patterned using the sacrificial layer etched with a taper angle as a mask.

In accordance with such an embodiment, a sacrificial layer is provided between a resist layer and a layer to be patterned. With the objects of the invention in view, there is also provided a method for fabricating a semiconductor structure, including the steps of providing a layer to be patterned at a semiconductor substrate, providing at least one sacrificial layer at the layer to be patterned, providing a resist layer at the sacrificial layer to dispose the sacrificial layer between the resist layer and the layer to be patterned, patterning the resist layer to form depressions therein, the depressions having dimensions, selectively etching the sacrificial layer with a taper angle in an etching direction dependent upon the dimensions of the depressions to create an etched sacrificial layer having etching dimensions smaller than the dimensions of the depression, and selectively etching the layer to be patterned using, as a mask, the etched sacrificial layer having the taper angle.

In principle, the sacrificial layer in the embodiment may be selected from a resist-like material. The sacrificial layer should, preferably, be chosen from a material such that a high selectivity is ensured during the etching of the layer to be patterned. Furthermore, the material should be chosen such that a selective etching of the sacrificial layer relative to the resist layer is possible beforehand. Furthermore, the sacrificial layer should, subsequently, be able to be removed easily or, if it is not removed, be tolerable in the semiconductor structure. The invention provides a large number of possibilities for the choice of the sacrificial layer, which may vary depending on the material of the layer to be patterned, the resist layer, and the requirements of the semiconductor structure. Examples of suitable, preferred materials are resist-like materials such as organic antireflection layers, bottom resists, or bilayer resists.

In accordance with another mode of the invention, an organic antireflection layer may, advantageously, be used as the sacrificial layer in a preferred embodiment. Such a layer is often situated below the actual resist layer in the semiconductor fabrication process. In the case of an etching of the layer with a controlled taper angle, the tapered layer may serve as a mask for the further patterning of the layer to be patterned that is situated underneath. In such a case, the layer to be patterned is, preferably, a polysilicon layer.

In accordance with the embodiment with one sacrificial layer, there are, likewise, many possibilities available for the layer to be patterned, such as, e.g., dielectrics, polysilicon, or metals used in semiconductor structures, such as, e.g., Ti, TiN, aluminum. Silicon oxide can be the dielectric layer. The term “metals” or “metal layer” , as used herein, encompass, in particular, also silicides that are often used in semiconductor fabrication, cobalt silicide, titanium silicide, and tungsten silicide being preferred. In principle, the possibility of a selective etching of the layer to be patterned should be ensured in correspondence with the sacrificial layer. The layer to be patterned is, preferably, a polysilicon layer.

In accordance with a further mode of the invention, there is provided the step of etching the layer to be patterned or the first sacrificial layer with the taper angle being between approximately 45 degrees and approximately 90 degrees, preferably, between approximately 70 degrees and approximately 85 degrees, in particular, approximately 80 degrees.

In accordance with an added feature of the invention, after etching the sacrificial layer with the taper angle, there is provided the step of, carrying out the selective etching of the layer step by patterning the layer to be patterned with depressions having dimensions no greater than approximately 180 nm, in particular, between approximately 55 nm and approximately 120 nm.

A further embodiment of the present invention provides a method in which two sacrificial layers are provided. With the objects of the invention in view, there is also provided a method for fabricating a semiconductor structure, having the following steps:

a. provision of a semiconductor substrate;

b. provision of two sacrificial layers between a layer to be patterned and a resist layer, the first sacrificial layer being disposed toward the resist layer, and the second sacrificial layer being disposed toward the layer to be patterned;

c. patterning of the resist layer in order to form a patterned resist layer;

d. selective etching of the first sacrificial layer with a taper angle in such a way as to reduce the dimensions within the first sacrificial layer in the etching direction that are prescribed by depressions situated in the patterned resist layer;

e. selective etching of the second sacrificial layer using the first sacrificial layer etched with a taper angle as a mask; and

f. selective etching of the layer to be patterned, the second etched sacrificial layer serving as a mask.

With the objects of the invention in view, there is also provided a method for fabricating a semiconductor structure, including the steps of providing a layer to be patterned at a semiconductor substrate, providing at least two sacrificial layers at the layer to be patterned with the second sacrificial layer being disposed toward the layer to be patterned and the first sacrificial layer disposed away from the layer to be patterned, providing a resist layer at the first sacrificial layer to dispose the first sacrificial layer between the resist layer and the second sacrificial layer, patterning the resist layer to form depressions therein, the depressions having dimensions, selectively etching the first sacrificial layer with a taper angle in an etching direction dependent upon the dimensions of the depressions to create an etched first sacrificial layer having etching dimensions smaller than the dimensions of the depressions, selectively etching the second sacrificial layer utilizing the first sacrificial layer, etched with the taper angle, as a mask, and selectively etching the layer to be patterned utilizing, as a mask, the second etched sacrificial layer.

Two sacrificial layers are provided in this embodiment according to the invention, i.e., a first sacrificial layer is supplemented by a further, underlying sacrificial layer. Such a configuration is advantageous, in particular, when the selectivity between the first sacrificial layer and the layer to be patterned is not sufficient during the patterning, which may be the case, for example, with dielectric materials to be patterned such as silicon oxide.

In principle, in such an embodiment, the sacrificial layer materials should, preferably, be selected so as to enable a selected etching with respect to the respectively adjacent layers. In particular, the first sacrificial layer should be able to be etched selectively with respect to the resist layer, the second sacrificial layer should be able to be etched selectively with respect to the first sacrificial layer, and, then, the layer to be patterned should be able to be etched selectively with respect to the second sacrificial layer. The person skilled in the art is afforded a multiplicity of possibilities for choosing the materials for the first sacrificial layer. By way of example, it is possible to use, as the first sacrificial layer, all dielectrics, such as, e.g., silicon nitride, silicon oxynitride, silicon oxide, all variations of polysilicon, doped or undoped, or metals such as, inter alia, Ti, TiN, aluminum or silicides, in particular, cobalt silicide, titanium silicide, and tungsten silicide. It is important, as mentioned, that the layers can be etched selectively relative to the adjacent layers. Moreover, the first sacrificial layer should, preferably, be able to be concomitantly removed during the etching of the layer to be patterned. This avoids having to remove two sacrificial layers after the patterning of the layer to be patterned.

The second sacrificial layer used is, preferably, a layer that is similar to the resist, e.g., an organic antireflection layer, carbon or, in principle, layers having carbon as the main constituent. The desired selectivity sequence can, thereby, be achieved. Such a structure: resist; dielectrics, polysilicon or metal as first sacrificial layer, and a layer similar to the resist as second sacrificial layer, ensures in each case the possibility of a selective etching both during the etching of the first sacrificial layer, of the second sacrificial layer, and during the patterning of the layer to be patterned. The second sacrificial layer is, particularly preferably, a carbon layer or a layer of a substantially carbon-containing material because the two sacrificial layers can, then, be removed nondestructively.

In such a case of two sacrificial layers, the first sacrificial layer, which is situated nearer to the resist layer, is, preferably, a silicon oxide layer, silicon nitride layer, or silicon oxynitride layer. Furthermore, the second sacrificial layer, which is situated nearer to the layer to be patterned, is, preferably, a carbon layer. It is, likewise, preferably the case that substantially only the first sacrificial layer situated nearer to the resist layer is etched with a taper angle so as to reduce the width of the depressions in the patterned resist layer within the first sacrificial layer in the etching direction, while the second sacrificial layer is substantially etched with straight edges. The first sacrificial layer having a reduced width of the depressions, compared with the original width in the resist layer after lithography, is available here, firstly, as a mask for the selective patterning of the second sacrificial layer, which can be etched selectively with straight edges. In such a case, in particular, the second sacrificial layer with straight edges, which has a smaller opening width than the resist layer after lithography, is, then, available as a mask layer for the patterning of the layer to be patterned. Such a method for implementation with two sacrificial layers is particularly preferred if the first sacrificial layer is a silicon oxide layer, the second sacrificial layer is a carbon layer, and the layer to be patterned is a dielectric, in particular, silicon oxide. This is because, in such a case, the carbon layer can be etched with straight edges highly selectively relative to the overlying silicon oxide sacrificial layer with an etched taper angle, after which there follows the further patterning of the layer to be patterned using the carbon layer as a mask. The fact that the carbon layer is etched with straight edges makes it possible to achieve, during the etching of the layer to be patterned, a narrower, controlled depression without a significant expansion of the depression. In a less preferred embodiment, the second layer may also be etched with a taper angle.

According to the invention, it is also possible to use a second sacrificial layer that remains as a layer in the semiconductor structure after the etching of the layer to be patterned if this does not disturb the construction of the semiconductor structure or this remaining layer is tolerable. This may be, e.g., a silicon oxide layer or silicon oxynitride layer. Such a combination that is, likewise, preferred according to the invention would be, e.g.: resist; first sacrificial layer polysilicon; second sacrificial layer silicon oxide or silicon oxynitride, layer to be patterned metal, e.g., aluminum. In such a case, a remainder of silicon oxide or silicon oxynitride is integratively tolerable as long as the silicon is removed from the first sacrificial layer during the metal patterning, which can be realized through a corresponding choice of the layer thicknesses.

In accordance with an additional feature of the invention, the first sacrificial layer etching step is carried out by etching substantially only the first sacrificial layer with the taper angle to reduce the dimensions within the first sacrificial layer, the dimensions being prescribed by the depressions in the patterned resist layer and the second sacrificial layer etching step is carried out by etching the second sacrificial layer substantially with straight edges.

In accordance with yet another feature of the invention, a polysilicon layer is selected as the first sacrificial layer, silicon oxide and/or silicon oxynitride is selected as the second sacrificial layer, and a metal layer is selected as the layer to be patterned.

According to the invention, the layer to be patterned may be selected from a multiplicity of materials as long as the abovementioned selectivity in combination with the other layers is ensured. Preferably, the layer to be patterned is a dielectric layer, preferably, silicon oxide, a metal layer, or a silicon layer.

In the methods according to the invention, further layers may also be present between the resist layer and the layer to be patterned, provided that this does not disturb the method according to the present invention. By way of example, in the case of the variant with two sacrificial layers (e.g., silicon oxide layer and carbon layer), an antireflection coating may, additionally, be present between the resist layer and the upper sacrificial layer in the etching direction.

The thickness of the sacrificial layers is, preferably, about 30-100 nm, more preferably, about 65-85 nm. It can be adapted to the required dimension reduction.

According to the present invention, the taper angle is, preferably, about 45-90 degrees, more preferably, about 70-85 degrees, and, most preferably, about 80°. A taper angle of 80° is to be sought due to the controllability and stability of the dimension reduction. The taper angle can be set by measures known to the person skilled in the art, such as, e.g., by use and proportions of the etching gases used or by the bias power, magnetic fields, temperatures set during the etching.

Preferably, after the etching with a taper angle, a new reduced depression width of less than or equal 180 nm is available for the patterning of the layer to be patterned, preferably, about 55 to 120 nm. It is, thus, possible, without having to perform measures on the lithography, to reduce the critical width to dimensions that are required for future technology generations.

All materials used in semiconductor fabrication can be used as the semiconductor substrate.

Other features that are considered as characteristic for the invention are set forth in the appended claims.

Although the invention is illustrated and described herein as embodied in a method for fabricating a semiconductor structure, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a fragmentary, cross-sectional view of a semiconductor structure with one sacrificial layer of a stage in a method according to the invention;

FIG. 2 is a fragmentary, cross-sectional view of the semiconductor structure of FIG. 1 in another stage of the method according to the invention;

FIG. 3 is a fragmentary, cross-sectional view of the semiconductor structure of FIG. 1 in another stage of the method according to the invention;

FIG. 4 is a fragmentary, cross-sectional view of a semiconductor structure with two sacrificial layers of a stage in a method according to the invention;

FIG. 5 is a fragmentary, cross-sectional view of the semiconductor structure of FIG. 4 in another stage of the method according to the invention;

FIG. 6 is a fragmentary, cross-sectional view of the semiconductor structure of FIG. 4 in another stage of the method according to the invention;

FIG. 7 is a fragmentary, cross-sectional view of the semiconductor structure of FIG. 4 in another stage of the method according to the invention;

FIG. 8 is a fragmentary, cross-sectional view of the semiconductor structure of FIG. 4 in another stage of the method according to the invention.

### DESCRIPTION OF THE PREFERRED EMBODIMENTS

In the figures of the drawings, unless stated otherwise, identical reference symbols denote identical parts.

Although applicable in principle to any desired integrated circuit, the present invention and the problem area on which it is based are explained with regard to semiconductor structures in silicon technology.

1. Etching With One Sacrificial Layer

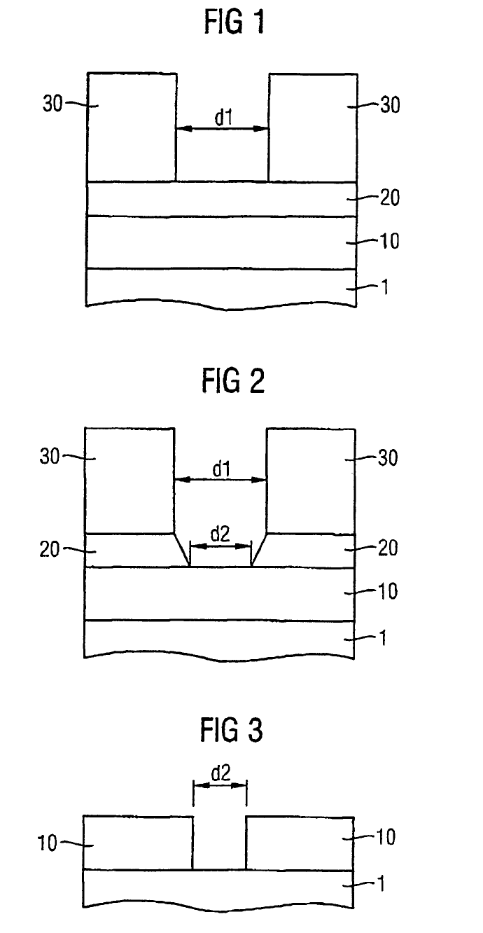

Referring now to the figures of the drawings in detail and first, particularly to FIG. 1 thereof, there is shown, situated on a semiconductor substrate 1 made of silicon, a layer 10 to be patterned, made of polysilicon with a thickness of 100 nm. A 70 nm thick layer of a conventional organic antireflection layer is deposited above that, and serves as sacrificial layer 20. Afterward, a resist layer 30 is applied and patterned lithographically. The hard mask in the lithography is provided for depression dimensions of 110 nm in this example. Correspondingly, depressions are obtained in the resist layer 30 with a critical width d1 of about 110 nm. Such a process state is illustrated in FIG. 1.

Afterward, the sacrificial layer 20 made of an organic antireflection coating is patterned with a taper angle of nominally about 85°. A reduction of the initial critical width from 110 nm to d2, approximately 95 to 100, nm is, thus, obtained over the 70 nm thick sacrificial layer 20. Such a process state is illustrated in FIG. 2.

Afterward, the polysilicon layer 10 to be patterned is patterned by selective etching, the organic antireflection layer 20 etched with a taper angle serving as a mask for the patterning. The process state after the patterning of the polysilicon layer 10 and removal of the sacrificial layer 20 is shown in FIG. 3. Overall, it is, thus, possible to pattern the layer 10 with significantly reduced dimensions of the depressions, without changing the lithography conditions.

2. Etching With Two Sacrificial Layers

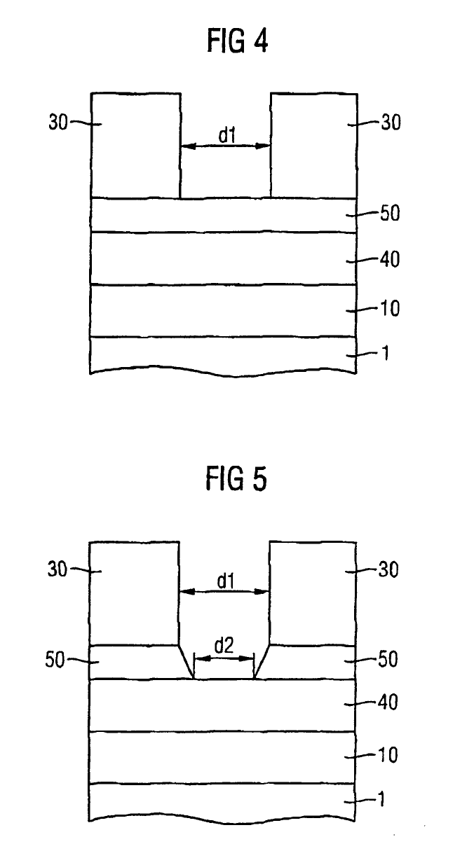

A layer 10 to be patterned made of silicon oxide is situated on a semiconductor substrate 1 made of silicon. Afterward, firstly, a carbon layer 40 having a thickness of about 150 nm is deposited and, then, a silicon oxide layer 50 having a thickness of about 85 nm is deposited, as sacrificial layers. A resist layer 30 is, then, deposited thereon, and subsequently is patterned lithographically. After the lithographic patterning, the resist layer 30, in the example, has depressions having a critical width d1 of about 130 nm. Such a process state is shown in FIG. 4. If required by the process, it is possible optionally for an antireflection layer to be introduced additionally between the upper sacrificial layer 50 made of silicon oxide and the resist layer 30. Afterward, through the resist or the resist layer 30, the 85 nm thick silicon oxide layer 50 is etched by plasma etching with a controlled taper angle of about 80°. A reduction of the critical width to d2 of about 100 nm is achieved within the sacrificial layer 50 made of silicon oxide. Such a process state is shown in FIG. 5.

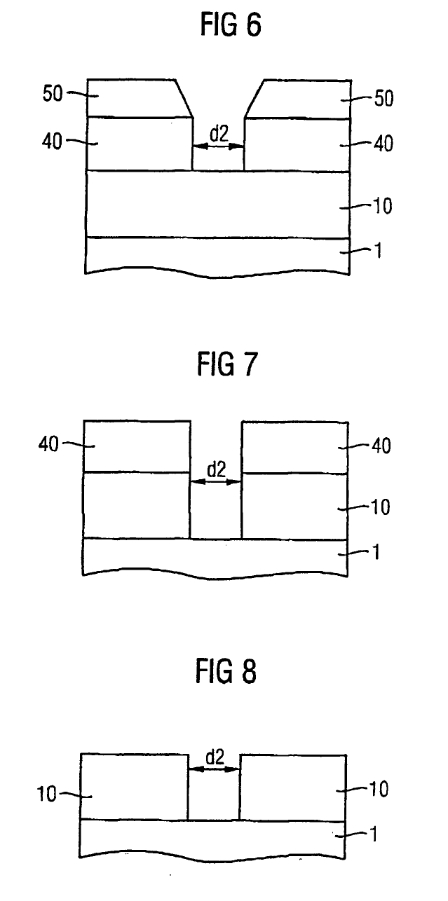

The upper sacrificial layer 50 etched in this way serves as a mask for the highly selective patterning by etching of the carbon sacrificial layer 40 situated underneath, which can, thus, be etched with straight edges through the sacrificial layer 50. A carbon mask having a critical width of 100 nm and straight edges is, thus, obtained, which serves as a mask for the patterning of the underlying silicon oxide layer with a layer thickness of 100 nm by selective etching. FIG. 6 shows the state after the etching of the sacrificial layer 50 with a taper and after the selective etching of the carbon sacrificial layer 40. The resist 30 is not illustrated or is removed here. The carbon sacrificial layer 40 is, then, available as a mask with depressions having a width of 100 nm for the patterning of the layer to be patterned by selective etching. The first sacrificial layer 50 is largely removed during the etching of the second sacrificial layer 40. FIG. 7 shows the state after the patterning of the actual layer 10 to be patterned and of the first sacrificial layer 50 that is removed in the process.

Afterward, the second sacrificial layer 40 (carbon) is removed by conventional methods. FIG. 8 shows the end state after the removal of the second sacrificial layer 40.

Overall, it is, thus, possible to pattern the layer 10 with significantly reduced dimensions of the depressions without changing the lithography conditions.

Although the present invention has been described above on the basis of preferred exemplary embodiments, it is not restricted thereto, but rather can be modified in diverse ways. In particular, the invention can be used whenever depressions with reduced dimensions are required in semiconductor structure fabrication.

Thus, the selection of the substrate materials, layer materials, layer thicknesses and combinations is only by way of example and can be varied in many different ways. The method according to the invention may be used e.g. to produce holes or depressions with reduced dimensions during the fabrication of contact holes.

This application claims the priority, under 35 U.S.C. § 119, of German patent application No. 103 12 469.1, filed Mar. 20, 2003; the entire disclosure of the prior application is herewith incorporated by reference.

We claim:

1. A method for fabricating a semiconductor structure, which comprises:
providing a layer to be patterned at a semiconductor substrate;
providing a sacrificial layer between the layer to be patterned and a resist layer;
patterning the resist layer to form a patterned resist layer with depressions;
selectively etching the sacrificial layer with a taper angle in an etching direction to reduce dimensions within the sacrificial layer in the etching direction, the dimensions being prescribed by the depressions in the patterned resist layer; and
selectively etching the layer to be patterned utilizing the sacrificial layer, etched with the taper angle, as a mask.

2. The method according to claim 1, which further comprises selecting a resist material as the sacrificial layer.

3. The method according to claim 1, which further comprises providing an organic antireflection layer as the sacrificial layer.

4. The method according to claim 1, which further comprises selecting the layer to be patterned from the group consisting of a dielectric layer, a metal layer, and a polysilicon layer.

5. The method according to claim 1, which further comprises etching the layer to be patterned with the taper angle being between approximately 45 degrees and approximately 90 degrees.

6. The method according to claim 1, which further comprises etching the layer to be patterned with the taper angle being between approximately 70 degrees and approximately 85 degrees.

7. The method according to claim 1, which further comprises etching the layer to be patterned with the taper angle of approximately 80 degrees.

8. The method according to claim 1, which further comprises after etching the sacrificial layer with the taper angle, carrying out the selective etching of the layer step by patterning the layer to be patterned with depressions having dimensions no greater than approximately 180 nm.

9. The method according to claim 1, which further comprises after etching the sacrificial layer with the taper angle, carrying out the selective etching of the layer step by patterning the layer to be patterned with depressions having dimensions between approximately 55 nm and approximately 120 nm.

10. The method according to claim 1, which further comprises after etching the sacrificial layer with the taper angle, carrying out the selective etching of the layer step by patterning the layer to be patterned with depressions having dimensions no greater than approximately 180 nm.

11. The method according to claim 1, which further comprises after etching the sacrificial layer with the taper angle, carrying out the selective etching of the layer step by patterning the layer to be patterned with depressions having dimensions between approximately 55 nm and approximately 120 nm.

12. A method for fabricating a semiconductor structure, which comprises:
providing a layer to be patterned at a semiconductor substrate;
providing at least one sacrificial layer at the layer to be patterned;
providing a resist layer at the sacrificial layer to dispose the sacrificial layer between the resist layer and the layer to be patterned;
patterning the resist layer to form depressions therein, the depressions having dimensions;
selectively etching the sacrificial layer with a taper angle in an etching direction dependent upon the dimensions of the depressions to create an etched sacrificial layer having etching dimensions smaller than the dimensions of the depression; and
selectively etching the layer to be patterned using, as a mask, the etched sacrificial layer having the taper angle.

13. The method according to claim 12, which further comprises selecting a resist material as the sacrificial layer.

14. The method according to claim 12, which further comprises providing an organic antireflection layer as the sacrificial layer.

15. The method according to claim 12, which further comprises selecting the layer to be patterned from the group consisting of a dielectric layer, a metal layer, and a polysilicon layer.

16. The method according to claim 12, which further comprises etching the sacrificial layer with the taper angle being between approximately 45 degrees and approximately 90 degrees.

17. The method according to claim 12, which further comprises etching the sacrificial layer with the taper angle being between approximately 70 degrees and approximately 85 degrees.

18. The method according to claim 12, which further comprises etching the sacrificial layer with the taper angle of approximately 80 degrees.

19. The method according to claim 12, which further comprises after etching the sacrificial layer with the taper angle, carrying out the selective etching of the layer step by patterning the layer to be patterned with depressions having dimensions no greater than approximately 180 nm.

20. The method according to claim 12, which further comprises after etching the sacrificial layer with the taper angle, carrying out the selective etching of the layer step by patterning the layer to be patterned with depressions having dimensions between approximately 55 nm and approximately 120 nm.

21. The method according to claim 12, which further comprises after etching the sacrificial layer with the taper angle, carrying out the selective etching of the layer step by patterning the layer to be patterned with depressions having dimensions no greater than approximately 180 nm.

22. The method according to claim 12, which further comprises after etching the sacrificial layer with the taper angle, carrying out the selective etching of the layer step by patterning the layer to be patterned with depressions having dimensions between approximately 55 nm and approximately 120 nm.

23. A method for fabricating a semiconductor structure, which comprises:
providing a layer to be patterned at a semiconductor substrate;
providing two sacrificial layers between the layer to be patterned and a resist layer with the first sacrificial layer disposed toward the resist layer and the second sacrificial layer being disposed toward the layer to be patterned;
patterning the resist layer to form a patterned resist layer with depressions;
selectively etching the first sacrificial layer with a taper angle in an etching direction to reduce dimensions within the first sacrificial layer, the dimensions being prescribed by the depressions in the patterned resist layer;
selectively etching the second sacrificial layer utilizing the first sacrificial layer, etched with the taper angle, as a mask; and
selectively etching the layer to be patterned utilizing the second etched sacrificial layer as a mask.

24. The method according to claim 23, which further comprises selecting the first sacrificial layer from the group consisting of a dielectric layer, a polysilicon layer, and a metal layer.

25. The method according to claim 24, which further comprises selecting the dielectric layer from the group consisting of silicon oxide, silicon oxynitride, and silicon nitride.

26. The method according to claim 23, which further comprises selecting a resist material as the second sacrificial layer.

27. The method according to claim 26, which further comprises selecting the resist material from the group consisting of an organic antireflection layer and a layer having carbon as the main constituent.

28. The method according to claim 23, which further comprises selecting a carbon layer as the second sacrificial layer.

29. The method according to claim 23, which further comprises:
carrying out the first sacrificial layer etching step by etching substantially only the first sacrificial layer with the taper angle to reduce the dimensions within the first sacrificial layer, the dimensions being prescribed by the depressions in the patterned resist layer; and
carrying out the second sacrificial layer etching step by etching the second sacrificial layer substantially with straight edges.

30. The method according to claim 23, which further comprises selecting the layer to be patterned from the group consisting of a dielectric layer, a metal layer, and a silicon layer.

31. The method according to claim 30, which further comprises selecting silicon oxide as the dielectric layer.

32. The method according to claim 23, which further comprises selecting:
a polysilicon layer as the first sacrificial layer;
one of the group consisting of silicon oxide and silicon oxynitride as the second sacrificial layer; and
a metal layer as the layer to be patterned.

33. The method according to claim 24, which further comprises selecting:
a polysilicon layer as the first sacrificial layer;
one of the group consisting of silicon oxide and silicon oxynitride as the second sacrificial layer; and
a metal layer as the layer to be patterned.

34. The method according to claim 30, which further comprises selecting:
a polysilicon layer as the first sacrificial layer;
one of the group consisting of silicon oxide and silicon oxynitride as the second sacrificial layer; and
a metal layer as the layer to be patterned.

35. The method according to claim 23, which further comprises etching first sacrificial layer with the taper angle being between approximately 45 degrees and approximately 90 degrees.

36. The method according to claim 23, which further comprises etching first sacrificial layer with the taper angle being between approximately 70 degrees and approximately 85 degrees.

37. The method according to claim 23, which further comprises etching first sacrificial layer with the taper angle of approximately 80 degrees.

38. The method according to claim 23, which further comprises after etching the first sacrificial layer with the taper angle, carrying out the selective etching of the layer step by at least one of patterning the layer to be patterned and etching the second sacrificial layer with depressions having dimensions no greater than approximately 180 nm.

39. The method according to claim 23, which further comprises after etching the first sacrificial layer with the taper angle, carrying out the selective etching of the layer step by at least one of patterning the layer to be patterned and etching the second sacrificial layer with depressions having dimensions between approximately 55 nm and approximately 120 nm.

40. A method for fabricating a semiconductor structure, which comprises:
providing a layer to be patterned at a semiconductor substrate;
providing at least two sacrificial layers at the layer to be patterned with the second sacrificial layer being disposed toward the layer to be patterned and the first sacrificial layer disposed away from the layer to be patterned;
providing a resist layer at the first sacrificial layer to dispose the first sacrificial layer between the resist layer and the second sacrificial layer;
patterning the resist layer to form depressions therein, the depressions having dimensions;
selectively etching the first sacrificial layer with a taper angle in an etching direction dependent upon the dimensions of the depressions to create an etched first sacrificial layer having etching dimensions smaller than the dimensions of the depressions;
selectively etching the second sacrificial layer utilizing the first sacrificial layer, etched with the taper angle, as a mask; and
selectively etching the layer to be patterned utilizing, as a mask, the second etched sacrificial layer.
